(19) United States
(12) Patent Application Publication
(10) Pub. No.: US 2025/0369110 A1
(43) Pub. Date: Dec. 4, 2025

(54) METHOD FOR FORMING A SEMICONDUCTOR STRUCTURE, METHOD FOR DEPOSITING A DIPOLE LAYER ON A SUBSTRATE, AND ASSOCIATED METHODS FOR FORMING A GATE STRUCTURE FOR A SEMICONDUCTOR DEVICE

(71) Applicant: ASM IP Holding B.V., Almere (NL)

(72) Inventors: Fu Tang, Gilbert, AZ (US); Eric James Shero, Phoenix, AZ (US); Ren-Jie Chang, Chandler, AZ (US)

(21) Appl. No.: 19/220,322

(22) Filed: May 28, 2025

Related U.S. Application Data
(60) Provisional application No. 63/654,844, filed on May 31, 2024.

(51) Int. Cl. C23C 16/455; C23C 16/34; C23C 16/40; C23C 16/56; H01L 21/28

(52) U.S. Cl. CPC C23C 16/45531; C23C 16/34; C23C 16/40; C23C 16/56; H01L 21/28158

(57) ABSTRACT

Methods for forming a semiconductor structure are disclosed. The methods disclosed include depositing a dipole layer comprising a ternary gallium material on a surface of a high-k dielectric material by a cyclical deposition process. Methods for depositing a dipole layer on a substrate by an atomic layer deposition process are also disclosed. Methods of forming a semiconductor device employing a ternary gallium material are also disclosed.

### CROSS-REFERENCE TO RELATED APPLICATIONS

This application is a nonprovisional of, and claims priority to and the benefit of, U.S. Provisional Patent Application No. 63/654,844, filed May 31, 2024 and entitled “METHOD FOR FORMING A SEMICONDUCTOR STRUCTURE, METHOD FOR DEPOSITING A DIPOLE LAYER ON A SUBSTRATE, AND ASSOCIATED METHODS FOR FORMING A GATE STRUCTURE FOR A SEMICONDUCTOR DEVICE,” which is hereby incorporated by reference herein.

### FIELD

The present disclosure relates generally to the field of semiconductor processing methods, and associated structures and to the field of device and integrated circuit manufacture. More particularly the present disclosure generally relates to methods for a dipole layer including gallium, as well as methods for forming a semiconductor device structure with a threshold voltage altered by employing a dipole layer including gallium.

### BACKGROUND

Transistors are integrated circuit components or elements that are often formed on a semiconductor substrate. Specifically, modern integrated circuits incorporate field-effect transistors (FETs) in which current flows through a semiconducting channel between a source and a drain, in response to a voltage applied to a control gate. The scaling of semiconductor devices, such as, for example, complementary metal-oxide-semiconductor (CMOS) devices, has led to significant improvements in speed and density of modern integrated circuits. In advanced CMOS devices, including central processing unit (CPU) and system-on-a-chip (SoC), structures with multiple threshold voltages are needed in order to optimize delay or power consumption. However, as device dimensions have shrunk, providing highly functional structures with multiple threshold voltages is facing serious challenges. For instance, one particular problem is controlling the threshold voltage of FETs.

State of the art solutions employ dipole layers for controlling the threshold voltage of transistors, e.g., by means of layers comprising oxides of one or more of lanthanum, scandium, and aluminum. However, the deposition of these layers may generate an oxide such as silicon oxide at the semiconductor-gate dielectric interface, which can increase the equivalent oxide thickness (EOT) of the device which negatively affects switching speed.

State of the art methods can comprise forming thick metallic layers on top of high-k layers which are then used to tune the threshold voltage. This necessitates fairly thick layers (1-4 nm) to achieve the required effective work function shift. However, the gate cavities for emerging scaled semiconductor devices do not provide enough space to deposit such thick films.

Therefore, there is a need for ways to achieve better performance while scaling down integrated circuits.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

As set forth in more detail below, various embodiments of the disclosure provide methods for forming structures suitable for a variety of applications. Exemplary methods can be used, for example, to form gallium containing dipole layers for metal-oxide-semiconductor (MOS) applications, such as in the formation of complimentary MOS (CMOS) devices. For example, gallium containing dipole layers can be used in the formation of logic devices, dynamic random-access memory (DRAM), three-dimensional NAND devices. However, unless noted otherwise, the invention is not necessarily limited to such examples.

According to one aspect, a method for forming a semiconductor structure is provided and the method comprises, providing a substrate within a reaction chamber, the substrate comprising a high-k dielectric layer; depositing a dipole layer comprising a ternary gallium material on a surface of the high-k dielectric layer by performing one or more cycles of a cyclical deposition process; wherein each cycle of the cyclical deposition process comprises: providing a first metal precursor comprising gallium to the reaction chamber; providing a second metal precursor comprising a second metal to the reaction chamber; and providing a first reactant to the reaction chamber, the first reactant comprising at one of an oxygen reactant, a nitrogen reactant, or a carbon reactant.

In some embodiments, the second metal precursor comprises one or more of a niobium precursor, a titanium precursor, a vanadium precursor, or a tungsten precursor.

In some embodiments, each cycle of the cyclical deposition process further comprises a super-cycle, each super-cycle comprising a first sub-cycle for depositing a first material comprising gallium and a second sub-cycle for depositing a second material comprising the second metal.

In some embodiments, the first sub-cycle and the second sub-cycle are performed with a sub-cycle ratio equal to greater than 1:2 in the super-cycle.

In some embodiments, the first sub-cycle comprises, providing the first metal precursor comprising gallium to the reaction chamber and providing the oxygen reactant to the reaction chamber, and the second sub-cycle comprising providing a niobium precursor to the reaction chamber and providing a second oxygen reactant to the reaction chamber.

In some embodiments, the first sub-cycle comprises, providing the first metal precursor comprising gallium to the reaction chamber and providing the nitrogen reactant to the reaction chamber, and the second sub-cycle comprising providing a niobium precursor to the reaction chamber and providing a second nitrogen reactant to the reaction chamber.

In some embodiments, the method further comprises contacting the dipole layer with a nitrogen-containing reactant thereby nitriding a portion of the dipole layer.

In some embodiments, contacting the dipole layer with the nitrogen-containing reactant is performed at temperature between 500° C. and 1000° C.

According to another aspect, a method for depositing a dipole layer on a substrate including a surface high-k dielectric layer by an atomic layer deposition (ALD) process is provided, the ALD process comprising: performing a plurality of super-cycles, each super-cycle comprising a gallium sub-cycle and a niobium sub-cycle; wherein the gallium sub-cycle comprises alternately and sequentially contacting the substrate with a gallium precursor and a first reactant comprising at least one of a first oxygen reactant, a first nitrogen reactant, or a first carbon reactant; and wherein the niobium sub-cycle comprises alternately and sequentially contacting the substrate with a niobium precursor and a second reactant comprising at least one of a second oxygen reactant, a second nitrogen reactant, or a second carbon reactant.

In some embodiments, the gallium sub-cycle and the niobium sub-cycle are performed with a sub-cycle ratio equal to or greater than 1:2 in the super-cycle.

In some embodiments, the first reactant and the second reactant comprise an oxygen reactant and the dipole layer comprise a niobium gallium oxide layer.

In some embodiments, the first reactant and the second reactant comprise a nitrogen reactant and the dipole layer comprises a niobium gallium nitride layer.

In some embodiments, the method further comprising contacting the dipole layer with a nitrogen-containing reactant thereby nitriding a portion of the dipole layer.

In some embodiments, contacting the dipole layer with the nitrogen-containing reactant is performed at temperature between 500° C. and 1000° C.

In some embodiments, the nitrogen-containing reactant comprises ammonia (NH₃).

According to another aspect, a method of forming a semiconductor device is provided, the method comprising: providing a substrate comprising a high-k dielectric layer; depositing a dipole layer on a surface of the high-k dielectric layer by performing a one or more of super-cycles of an atomic layer deposition process, each super-cycle comprising a gallium sub-cycle and a second metal sub-cycle; contacting the dipole layer with a nitrogen-containing reactant thereby nitriding a portion of the dipole layer; thermally treating the substrate with the high-k dielectric layer and the dipole layer thereon at temperature between 500° C. and 1000° C.; selectively etching the dipole layer to expose the high-k dielectric layer; and depositing a conducting layer on the high-k dielectric layer.

In some embodiments, the gallium sub-cycle comprises alternately and sequentially contacting the substrate with a gallium precursor and a first reactant comprising at least one of a first oxygen reactant, a first nitrogen reactant, or a first carbon reactant.

In some embodiments, the second metal sub-cycle comprises alternately and sequentially contacting the substrate with a second metal precursor comprising one or more of a niobium precursor, a titanium precursor, a vanadium precursor, or a tungsten precursor and a second reactant comprising at least one of a second oxygen reactant, a second nitrogen reactant, or a second carbon reactant.

In some embodiments, contacting the dipole layer with the nitrogen-containing reactant comprises contacting the dipole layer with ammonia (NH₃) at temperature between 500° C. and 1000° C.

In some embodiments, the dipole layer provides a voltage shift to the semiconductor device between 10 mV and 50 mV per Angstrom of thickness of the deposited dipole layer.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures. the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary method in accordance with one or more embodiments of the disclosure.

FIG. 2 illustrates an additional exemplary method in accordance with one or more embodiments of the disclosure.

FIG. 3 illustrates an exemplary substrate in accordance with one or more embodiments of the disclosure.

FIG. 4 illustrates a semiconductor structure formed in accordance with one or more embodiments of the disclosure.

FIG. 5 illustrates an additional semiconductor structure formed in accordance with one or more embodiments of the disclosure.

FIG. 6 illustrates a further semiconductor structure formed in accordance with one or more embodiments of the disclosure.

FIG. 7 illustrates a semiconductor device structure formed in accordance with one or more embodiments of the disclosure.

FIG. 8 illustrates a further exemplary method in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “gas” can include material that is a gas at normal temperature and pressure (NTP), a vaporized solid and/or a vaporized liquid, and can be constituted by a single gas or a mixture of gases, depending on the context. A reactant may be provided to the reaction chamber in the gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. The substrate can include various topologies, such as gaps, including recesses, lines, trenches, or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

As used herein, the term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

As used herein, the term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

As used herein, the term “dipole layer” may refer to a layer (or layers) of material that induce a shift in the effective work function of a metal-oxide-semiconductor structure when formed in, on or over a gate dielectric of said metal-oxide-semiconductor structure. For example, a shift in the effective work function of a metal-oxide-semiconductor structure can result in a threshold voltage shift of a transistor comprising said metal-oxide-semiconductor structure.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly, to this, it will be understood the term “under,” “underlying,” or “below” will be construed to be relative concepts.

Various embodiments of the present disclosure relate to methods for forming a semiconductor structure including a dipole layer comprising gallium. In more detail, a dipole layer may be employed within a gate stack of a metal-oxide-semiconductor (MOS) device to modulate the effective work function (eWF) of the overall gate stack to improve the performance of the MOS devices. In some embodiments, a dipole layer can be formed, e.g., by a deposition process, over, or directly over the gate dielectric of a metal-oxide-semiconductor (MOS) device, and the properties of the dipole layer (including, but not limited to, material composition, thickness, and deposition method) can alter the band alignment in the MOS device to a provide a device with a preferred operating performance. In particular embodiments, a change in the thickness of a dipole layer disposed over a gate dielectric of a MOS device may induce a significant shift in the threshold voltage of said MOS device. Therefore, in some embodiments, a dipole layer which is relatively inert to thickness changes that could potentially be brought about by subsequent MOS device fabrication processes may be desirable.

As a non-limiting example, gallium oxide (GaOₓ) has emerged as a potential candidate for use in dipole layers. However, gallium oxide dipole layer may exhibit an exceedingly high thickness to voltage shift sensitivity, e.g., the voltage shift induced per Angstroms of thickness of the dipole layer (Vₜₕ/Angstrom). A high Vₜₕ/Angstrom sensitivity can necessitate extreme thickness uniformity control requirements when forming gallium oxide dipole layers, making deposition of such dipole layers exceedingly challenging. In addition, such a high Vₜₕ/Angstrom sensitivity may leave little room for fine tuning and/or incremental adjustment of the properties of the dipole layer and likewise the semiconductor devices fabricated employing such dipole layer. Furthermore, gallium oxide dipole layers may cause an equivalent oxide thickness (EOT) penalty when employed in the fabrication of devices structures which can negatively impact the performance of such devices.

Therefore, the various embodiments of the disclosure include methods for forming dipole layers that include a gallium containing material in which the Vₜₕ/Angstrom sensitivity is reduced. In such embodiments, the gallium containing dipole layers can comprise a ternary gallium material tailored in thickness and composition to achieve a desired voltage shift with increased control, uniformity, and repeatability.

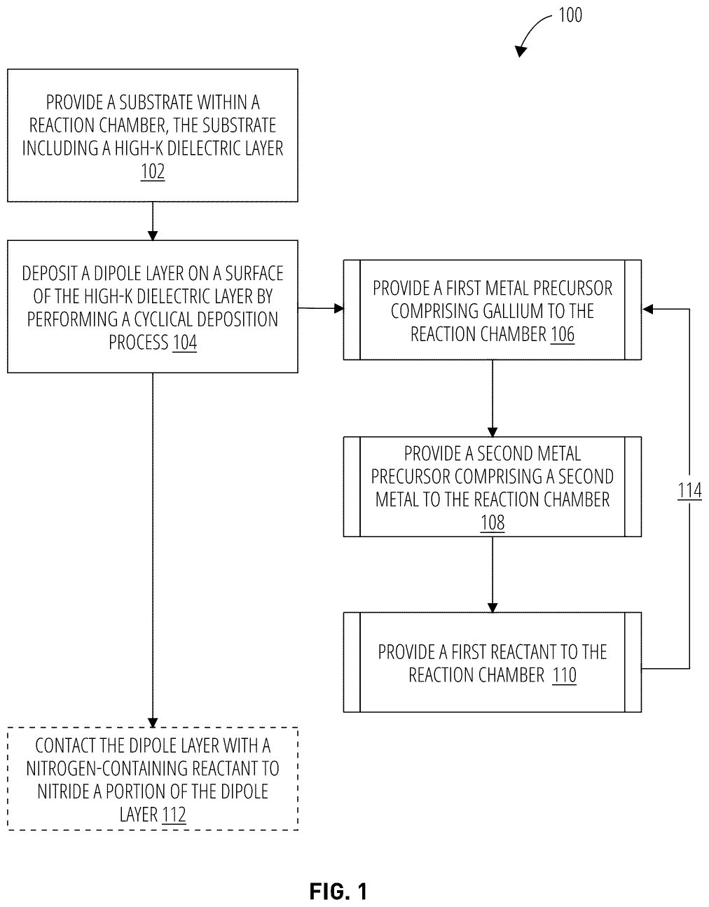

Turning now to the figures, FIG. 1 illustrates an exemplary method 100 for forming a semiconductor structure including a dipole layer comprising a ternary gallium material.

In accordance with examples of the disclosure, method 100 can include a step 102 comprising providing a substrate within a reaction chamber.

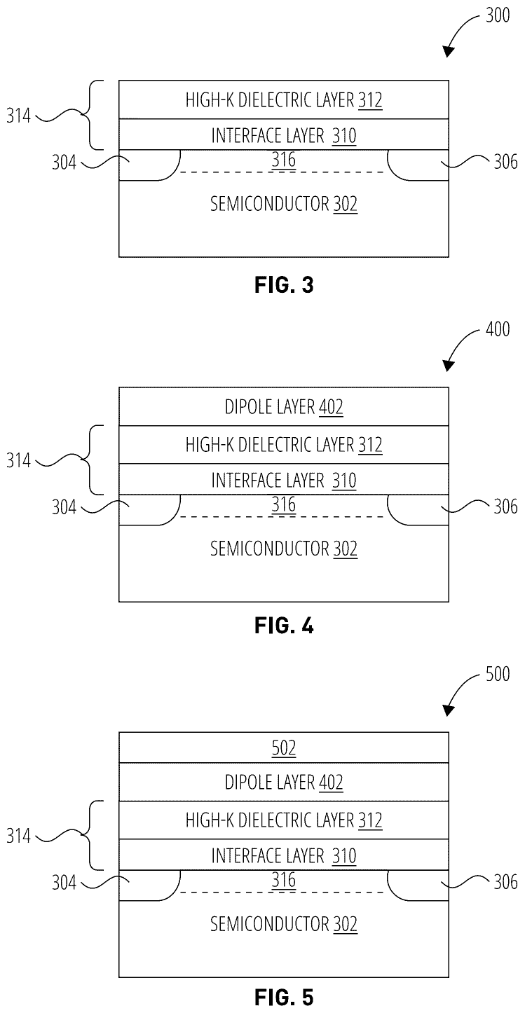

In accordance with examples of the disclosure, the substrate can comprise a partially fabricated device structure. As a non-limiting example, FIG. 3 illustrates a substrate 300 which comprises a semiconductor 302 including a source region 304 and a drain region 306 with a channel region 308 disposed between the source and drain regions. The substrate 300 may also include a dielectric material 314. For example, the dielectric material 314 may include an interface layer 310 disposed on the channel region. In some embodiments, the interface layer 310 may comprise a silicon oxide layer (e.g., SiO₂). The dielectric material 314 may also include a high-k dielectric layer 312 disposed over the interface layer 310. The high-k dielectric layer 312 overlying the semiconductor 302 may include materials having a dielectric constant greater than the dielectric constant of silicon dioxide, such as hafnium oxide, for example.

In accordance with examples of the disclosure, the reaction chamber can be, or include, a reaction chamber of semiconductor deposition apparatus configured for performing cyclical deposition processes, such as, an atomic layer deposition apparatus. The reaction chamber can be a standalone reaction chamber or part of a cluster tool. The reaction chamber may be part of a batch processing tool. In some embodiments, a flow-type reaction chamber may be utilized. In some embodiments, a showerhead-type reaction chamber may be utilized. In some embodiments, a space divided reaction chamber may be utilized. In some embodiments, a high-volume manufacturing-capable single wafer reaction chamber may be utilized. In other embodiments, a batch reaction chamber comprising multiple substrates may be utilized. For embodiments in which a batch reaction chamber is used, the number of substrates may be in the range of 10 to 200, or 50 to 150, or even 100 to 130. The reactor can be configured as a thermal reactor-with no plasma excitation apparatus. Alternatively, the reaction chamber can include direct and/or remote plasma apparatus.

In accordance with examples of the disclosure, the substrate disposed within the reaction chamber may be heated to a desired deposition temperature. In such examples the substrate may be heated to a substrate temperature of less than 800° C., less than 600° C., less than 400° C., or even less than 200° C. In some embodiments of the disclosure, the substrate temperature may be greater than room temperature, between 200° C. and 800° C., between 200° C. and 600° C., or between 200° C. and 400° C.

In accordance with examples of the disclosure, in addition to controlling the temperature of the substrate, the pressure in the reaction chamber may also be regulated to enable deposition of desired dipole layer. In such examples, the pressure within the reaction chamber may be less than 760 Torr, between 0.1 Torr and 10 Torr, between 0.5 Torr and 5 Torr, or between 1 Torr to 4 Torr.

In accordance with examples of the disclosure, method 100 (FIG. 1) also comprises depositing a dipole layer comprising a ternary gallium material on a surface of the high-k dielectric layer by performing one or more deposition cycle of a cyclical deposition process (step 104). In such examples, each deposition cycle of the cyclical deposition process can comprise providing a first metal precursor comprising gallium to the reaction chamber (sub-step 106), providing a second metal precursor comprising a second metal to the reaction chamber (sub-step 108), and providing a first reactant to the reaction chamber, the first reactant comprising at least one of an oxygen reactant, a nitrogen reactant, or a carbon reactant (sub-step 110). Sub-steps 106, 108 and 110 can be repeated as illustrated by cycle loop 114.

In accordance with examples of the disclosure, sub-steps 106, 108, and 110 can be initiated and/or terminated in any order. In some embodiments, sub-steps 106, 108, and 110 can be performed concurrently, or at least with some temporal overlap between the sub-steps of the cyclical deposition process (step 104). In some embodiments the cyclical deposition process (step 104) can include one or more (e.g., 1-10 or 1-5) repetitions of each sub-steps 106, 108, and/or 110 prior to proceeding to the subsequent sub-steps 106, 108, or 110.

In addition, in some embodiments, additional sub-steps can be included in the cyclical deposition process (step 104). In such embodiments the one or more additional sub-steps can be performed during each cycle of the cyclical deposition process or alternatively the one or more additional sub-steps may be performed during selected cycles of the cyclical deposition process. In accordance with examples of the disclosure, a purging step (to remove excess precursor and any reaction byproducts from the reaction chamber) can be performed after having performed one or more of sub-steps 106, 108, and 110.

As a non-limiting examples, a deposition cycle may comprise providing a first metal precursor comprising gallium to the reaction chamber (sub-step 106), a purging step, providing a second metal precursor comprising a second metal to the reaction chamber (sub-step 108), a purging step, providing a first reactant to the reaction chamber (sub-step 110), and a purging step.

### Galllium Precursor Sub-Step 106

In accordance with examples of the disclosure, during sub-step 106 a first metal precursor comprising a gallium precursor is provided to the reaction chamber. The gallium precursor can be pulsed to the reaction chamber. The term “pulse” can be understood to comprise feeding a precursor into the reaction chamber for a predetermined amount of time. Unless otherwise noted, the term “pulse” does not restrict the length or duration of the pulse and a pulse may be any length of time. The gallium precursor pulse may be supplied to the reaction chamber along with a carrier gas flow. In some embodiments, the gallium precursor may comprise a volatile gallium species that is reactive with the surface(s) of the substrate. The gallium precursor pulse may self-saturate the substrate surfaces such that excess constituents of the gallium precursor pulse do not further react with the molecular layer formed by this process.

The gallium precursor pulse is preferably supplied as a vapor phase reactant. The gallium precursor gas may be considered “volatile” for the purposes of the present disclosure if the species exhibits sufficient vapor pressure under the process conditions to transport species to the substrate surface in sufficient concentration to saturate the exposed surfaces.

In accordance with some embodiments of the disclosure, the gallium precursor can include one or more of a gallium halide compound, a gallium oxyhalide compound, a gallium organometallic compound, a gallium metal organic compound, or the like.

In accordance with examples of the disclosure, the gallium precursor may comprise one or more of a gallium beta diketonate compound, a gallium alkoxide compound, a gallium alkyl compound, a gallium alkylamide compound, a gallium halide compound, and a gallane compound. In one aspect, the gallium precursor may comprise one or more gallium beta diketonates compounds, such as, for example, gallium tris-acetylacetonate, and tris(2,2,6,6-tetramethyl-3,5-heptanedionato)gallium(III). In one aspect, the gallium precursor may comprise one or more gallium alkyl compounds, such as, for example, tricthylgallium (TEG), and trimethylgallium (TMG). In one aspect, the gallium precursor may comprise one or more gallium alkylamide compounds, such as, gallium tris(dimethylamide) (TDMAGa), for example. In one aspect, the gallium precursor may comprise one or more gallium halide compounds, such as gallium monochloride, gallium trichloride, gallium tribromide, and gallium tri-iodide.

As a non-limiting example, the gallium precursor may comprise gallium tris(dimethylamide), gallium (III) acetylacetonate (Ga(acac)₃), gallium alkoxides, such as dimethylgallium isopropoxide, and/or gallium alkyls, such as, trimethylgallium (TMGa). In some embodiments, carboxylates of gallium can be used as precursors, for example, gallium triacetate or gallium tripropionate.

### Second Metal Precursor Sub-Step 108

In accordance with examples of the disclosure, during sub-step 108 a second metal precursor is provided to the reaction chamber. The second metal precursor can be pulsed to the reaction chamber, as described previously. The second metal precursor pulse may be supplied to the reaction chamber along with a carrier gas flow. In some embodiments, the second metal precursor may comprise a volatile metal species that is reactive with the surface(s) of the substrate. The second metal precursor pulse may self-saturate the substrate surfaces such that excess constituents of the second metal precursor pulse do not further react with the molecular layer formed by this process.

The second metal precursor pulse is preferably supplied as a vapor phase reactant. The second metal precursor may be considered “volatile” for the purposes of the present disclosure if the species exhibits sufficient vapor pressure under the process conditions to transport species to the substrate surface in sufficient concentration to saturate the exposed surfaces.

In accordance with examples of the disclosure, the second metal precursor may be pulsed to the reaction chamber for a time period sufficient to form a monolayer or a sub-monolayer of a second metal species on a surface of the substrate. Subsequently, excess second metal precursor may be purged by stopping the flow of the second metal precursor while continuing to flow a carrier gas, a purge gas, or a gas mixture, for a sufficient time to diffuse or purge excess precursor and any reactant by-products from the reaction chamber.

In accordance with further examples of the disclosure, the second metal precursor may be pulsed to the reaction chamber along with the gallium precursor. In such examples, the sub-step 106 and the sub-step 108 can be performed concurrently, or at least with some temporal overlap between the sub-steps. In such examples, the gallium precursor and the second metal precursor may be pulsed to the reaction chamber for a time period sufficient to form a monolayer or a sub-monolayer of a gallium species and a second metal species on a surface of the substrate. Subsequently, excess gallium precursor and second metal precursor may be purged by stopping the flow of the gallium precursor and the second metal precursor while continuing to flow a carrier gas, a purge gas, or a gas mixture, for a sufficient time to diffuse or purge excess precursor and any reactant by-products from the reaction chamber.

In accordance with examples of the disclosure, the second metal precursor can include one or more of a metal halide compound, a metal oxyhalide compound, an organometallic compound, a metal organic compound, or the like. In such examples, the second metal precursor can comprise a transition metal precursor. In such examples, the second metal precursor can comprise one or more of a niobium precursor, a titanium precursor, a vanadium precursor, or a tungsten precursor.

In some embodiments, the second metal precursor comprises a niobium precursor. In one aspect the niobium precursor can comprise one or more niobium halide compounds, such as, for example, NbCl₅, or NbF₅. In another aspect the niobium precursor can comprise one or more niobium metalorganic/organometallic compounds, such as, for example, Nb(N^{t}Bu)(NEt₂)₃, Nb(N^{t}Bu)(NEt₂)₂(Cp), Nb(N^{t}Bu)(NEtMe)₃, Nb(OEt)₅, or Nb(OEt)₅.

In some embodiments, the second metal precursor comprises a titanium precursor. In one aspect the titanium precursor can comprise one or more titanium halide compounds, such as, for example, TiCl₄, TiF₄, or TiI₄. In another aspect the titanium precursor can comprise one or more titanium metalorganic/organometallic compounds, such as, for example, Ti(NEt₂)₄, Ti(NEtMe)₄, Ti(NMe₂)₄, TiCp₂((ⁱPrN)₂C(NHⁱPr)), Ti(Cp)CHT, Ti(CpMe)(OⁱPr)₃, Ti(CpMe₅)(OMe)₃, Ti(NEt₂)₄, Ti(NMe₂)₃(CpMe), or Ti(NMe₂)₃(CpN).

In some embodiments, the second metal precursor comprises a vanadium precursor. In one aspect the vanadium precursor can comprise one or more vanadium halide compounds, such as, for example, VCl₃, or VOCl₃. In another aspect the vanadium precursor can comprise one or more vanadium metalorganic/organometallic compounds, such as, for example, VO(acac)₂, V(NEt₂)₄ Ti(NEtMe)₄, V(NEtMe)₄, V(NMe₂)₄, V(ⁱPrAMD)₃, or VO(OⁱPr)₃.

In some embodiments, the second metal precursor comprises a tungsten precursor. In one aspect the tungsten precursor can comprise one or more tungsten halide compounds, such as, for example, WCl₅, or WF₆. In another aspect the tungsten precursor can comprise one or more tungsten metalorganic/organometallic compounds, such as, for example, W(N^{t}Bu)₂(NMe₂)₂, W₂(NMe₂)₆, WH₂Cp₂, W(N^{t}Bu)₂(ⁱPrAMD)₂, WH₂(ⁱPrCp)₂, WO₂(^{t}BuAMD)₂, or W(CO)(₃-hexyne)₃.

### Co-Reactants Sub-Step 110

In accordance with examples of the disclosure, the cyclical deposition process 104 (FIG. 1) may further comprise providing a first reactant to the reaction chamber (sub-step 110). In such examples, the first reactant comprises at least one of an oxygen reactant, a nitrogen reactant, or a carbon reactant.

In some embodiments, the first reactant comprises an oxygen reactant. In one aspect the oxygen reactant can comprise one or more of water (H₂O), hydrogen peroxide (H₂O₂), ozone (O₃), oxides of nitrogen, such as, for example, nitrogen monoxide (NO), nitrous oxide (N₂O), and nitrogen dioxide (NO₂). In some embodiments, the oxygen reactant comprises an organic alcohol, such as, isopropyl alcohol, for example.

In some embodiments the first reactant comprises a nitrogen reactant. In some embodiments, the nitrogen reactant can comprise one or more of ammonia (NH₃), hydrazine (N₂H₄), other nitrogen and hydrogen-containing gases (e.g., a mixture of nitrogen gas and hydrogen gas), and the like. The nitrogen reactant can include or consist of nitrogen and hydrogen. In some cases, the nitrogen reactant does not include diatomic nitrogen. In some embodiments, the nitrogen reactant comprises a substituted hydrazine compound. In such embodiments, the substituted hydrazine compound may comprise an alkyl-hydrazine selected from the group consisting of: tertbutylhydrazine (C₄H₉N₂H₃), methylhydrazine (CH₃NHNH2), dimethylhydrazine (C₂H₃N₂) and diethylhydrazine (C₄H₁₂N₂). In some embodiments, the substituted hydrazine compound may comprise one or more of 1,1-diethylhydrazine, 1-ethyl-1-methylhydrazine, isopropylhydrazine, phenylhydrazine, 1,1-diphenylhydrazine, 1,2-diphenylhydrazine, N-methyl-N-phenylhydrazine, 1,1-dibenzylhydrazine, 1,2-dibenzylhydrazine, 1-ethyl-1-phenylhydrazine, 1-methyl-1-(m-tolyl)hydrazine, and 1-ethyl-1-(p-tolyl)hydrazine.

In some embodiments the first reactant comprises a carbon reactant. In one aspect the carbon reactant may be provided as a component of the gallium precursor and/or the second metal precursor. For example, the gallium precursor and/or the second metal precursor may comprise a compound including a carbon component, such as, for example, when employing a gallium metalorganic/organometallic compound as the gallium precursor and/or when employing a metalorganic/organometallic compound as the second metal precursor. In such examples, the sub-step 110 of providing the carbon reactant to the reaction chamber may be performed by either sub-step 106 and/or sub-step 108.

In accordance with examples of the disclosure, the sub-step 110 of providing a carbon reactant to the reaction chamber may comprise providing a separate carbon reactant to the reaction chamber (i.e., the carbon reactant is not provided during sub-step 106 and/or sub-step 108 by a metalorganic/organometallic compound). In such examples, the carbon reactant may comprise one or more of acetylene, ethylene, alkyl halide compounds, alkene halide compounds, metal alkyl compounds, and the like. Exemplary alkyl halide compounds include CX₄, CHX₃, CH₂X₂, CH₃X, where X═F, Cl, Br, or I. Exemplary alkene halide compounds include C₂H₃X, C₂H₂X₂, C₂HX₃, and C₂X₄, where X═F, Cl, Br, or I. Exemplary alkyne halide compounds include C₂X₂ and HC₂X, where X═F, Cl, Br, or I.

In accordance with examples of the disclosure, the sub-steps 106, 108 and 110 (and any intervening purge sequences) may constitute a deposition cycle and a deposition cycle may be repeated one or more times to deposit a dipole layer comprising a ternary gallium material to a desired thickness and composition over the substrate (e.g., over the substrate 300 of FIG. 3), and particularly over the high-k dielectric layer 312. A deposition cycle may be repeated multiple times, the number of repetitions being decided based on, for example, the desired thickness of the dipole layer to be deposited and/or the degree of voltage shift desired in a semiconductor device structure, e.g., the desired thickness/composition of the ternary gallium material containing dipole layer. For example, if the thickness of the dipole layer is less than desired for a particular application, then the step of providing a gallium precursor to the reaction chamber (sub-step 106), providing a second metal precursor (sub-step 108), and providing a first reactant (sub-step 110) can be repeated one or more times. Once the dipole layer comprising a ternary gallium material has been deposited to a desired thickness/composition, the substrate can be subjected to additional processes to form a desired structure and/or device, such as, a metal-oxide-semiconductor device, for example, as described below.

In accordance with examples of the disclosure, each deposition cycle of the cyclical deposition process (step 104) may further comprise performing one or more super-cycles. In some embodiments, each super-cycle may comprise a first sub-cycle for depositing a first material comprising gallium and a second sub-cycle for depositing a second material comprising the second metal.

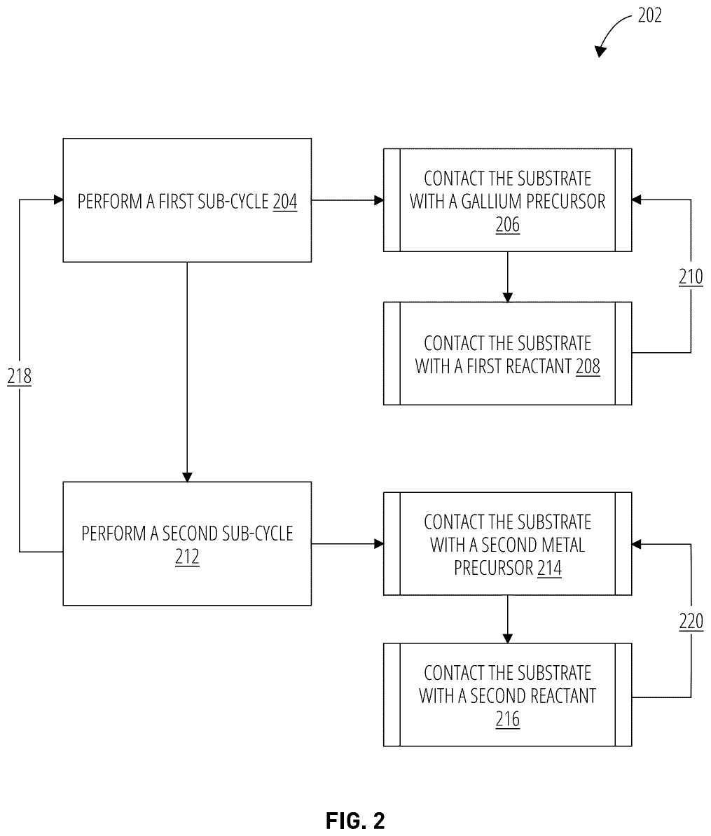

FIG. 2 illustrates a non-limiting example of the cyclical deposition process (step 102) of FIG. 1 as a super-cycle cyclical deposition process 202. In accordance with examples of the disclosure, each super-cycle comprises performing a first sub-cycle (204) one or more times and performing a second sub-cycle (212) one or times. In such examples, the super-cycle can be repeated as desired, as indicated by super-cycle loop 218 to deposit a ternary gallium material of a desired thickness and composition. In addition, after completion of a sub-cycle (204 and/or 212) a purging step may be performed. In addition, although the super-cycle cyclical deposition process 202 is illustrated in FIG. 2 as first performing the first sub-cycle 204 followed by the second sub-cycle 212, the super-cycle cyclical deposition process 202 may be performed by first performing second sub-cycle 212 followed by first sub-cycle 204.

In accordance with examples of the disclosure, the first sub-cycle 204 (FIG. 2) may comprise providing a first metal precursor comprising gallium to the reaction chamber (sub-step 206) and providing a first reactant to the reaction chamber (sub-step 208). The sub-step 206 and the sub-step 208 can be initiated and/or terminated in any order. In some embodiments, sub-steps 206 and 208 can be performed concurrently, or at least with some temporal overlap. In some embodiments the first sub-cycle 204 can include one or more (e.g., 1-10 or 1-5) repetitions of each sub-step 206 and/or 208 prior to proceeding to the subsequent sub-steps. In addition, additional sub-steps can be included in the first sub-cycle 204 which may be performed during each sub-cycle or alternatively may be performed during selected sub-cycles. In accordance with examples of the disclosure, a purging step (to remove excess precursor and any reaction byproducts from the reaction chamber) can be performed after having performed one or more of sub-steps 206 and/or 208. In accordance with examples of the disclosure, the first sub-cycle 204 may be repeated one more or more times (as illustrated by first sub-cycle loop 210) prior to performing subsequent processes in the super-cycle cyclical deposition process 202 (e.g., such as performing the second sub-cycle 212).

In accordance with further examples of the disclosure, the second sub-cycle 212 (FIG. 2) may comprise providing a second metal precursor (e.g., Nb, Ti, V, or W) to the reaction chamber (sub-step 214) and providing a second reactant to the reaction chamber (sub-step 216). The sub-step 214 and the sub-step 216 can be initiated and/or terminated in any order. In some embodiments, sub-steps 214 and 216 can be performed concurrently, or at least with some temporal overlap. In some embodiments the second sub-cycle 212 can include one or more (e.g., 1-10 or 1-5) repetitions of each sub-step 214 and/or 216 prior to proceeding to the subsequent sub-steps. In addition, additional sub-steps can be included in the second sub-cycle 212 which may be performed during each sub-cycle or alternatively may be performed during selected sub-cycles. In accordance with examples of the disclosure, a purging step (to remove excess precursor and any reaction byproducts from the reaction chamber) can be performed after having performed one or more of sub-steps 214 and/or 216. In accordance with examples of the disclosure, the second sub-cycle 212 may be repeated one more or more times (as illustrated by second sub-cycle loop 220) prior to performing subsequent processes in the super-cycle cyclical deposition process 202 (e.g., such as performing the first sub-cycle 204).

In accordance with examples of the disclosure, the super-cycle cyclical deposition process 202 (FIG. 2) comprising the two sub-cycles (204 and 212) may be written as: {[gallium precursor+first reactant]×N₁+[second metal precursor+second reactant]×N₂}×N₃, where N₁, N₂, and N₃ are real integers, and the square brackets represent one sub-cycle whereas the curved brackets represent on super-cycle.

In accordance with examples of the disclosure, the number of times that each sub-cycle is performed may be the same in each super-cycle or may vary. In accordance with further examples of the disclosure, the number of times that the first sub-cycle 204 is performed (i.e., N₁) compared with the number of times the second sub-cycle 212 is performed (i.e., N₂) may be independently varied in each super-cycle.

In accordance with examples of the disclosure, the number of times that the first sub-cycle 204 (N₁) is performed as a ratio to the number of times the second sub-cycle 212 is performed (N₂) may be varied to achieve a desired composition of the dipole layer comprising the ternary gallium material. In such examples, the first sub-cycle may be performed once and the second sub-cycle 212 may be performed once, giving a sub-cycle ratio (N₁:N₂) of 1:1 for the super-cycle. In further examples, the first sub-cycle may be performed once and the second sub-cycle 212 may be performed twice, giving a sub-cycle ratio (N₁:N₂) of 1:2 for the super-cycle. In further examples, the first sub-cycle may be performed once and the second sub-cycle 212 may be performed three times, giving a sub-cycle ratio (N₁:N₂) of 1:3 for the super-cycle. In some embodiments, the sub-cycle ratio (N₁:N₂) may be 1:1, 1:2, 1:3, 1:4, 1:5, 1:6, 1:7, 1:8, 1:9, or 1:10. In alternative embodiments, the sub-cycle ratio (N₁:N₂) may be 10:1, 9:1, 8:1, 7:1, 6:1, 5:1, 4:1, 3:1, 2:1, or 1:1. In some embodiments, the sub-cycle ratio (N₁:N₂) may be greater than 1:2, 1:3, 1:5, 1:7, or 1:10. In some embodiments, the sub-cycle ratio (N₁:N₂) may be less than 10:1, 7:1, 5:1, 3:1, or 2:1.

In accordance with examples of the disclosure, the super-cycle (comprise sub-cycles 204 and 212) may be repeated one, two or more times, and the like, to achieve a dipole layer of the desired thickness and composition.

In accordance with particular examples of the disclosure, the first sub-cycle (204) may comprises providing the first metal precursor comprising gallium to the reaction chamber (sub-step 206) and providing a first reactant comprising an oxygen reactant to the reaction chamber (sub-step 208), and the second sub-cycle may comprise providing a second metal precursor comprising a niobium precursor to the reaction chamber (sub-step 214) and providing a second reactant comprising an addition oxygen reactant to the reaction chamber (sub-step 216). In such examples, the oxygen reactant (i.e., the first reactant) and the additional oxygen reactant (i.e., the second reactant) may comprise the same oxygen reactant or alternatively may comprise different oxygen reactants. In such examples, the dipole layer deposited by the super-cycle cyclical deposition process 202 may comprise a niobium gallium oxide layer (NbGaO). In such examples, the sub-cycle ratio (N₁:N₂) may be varied to achieve a desired Ga/Nb ratio composition in the deposited niobium gallium oxide layer. For example, the sub-cycle ratio (N₁:N₂) (for a desired Ga/Nb ratio in the niobium gallium oxide layer) may be 1:1, 1:2, 1:3, 1:4, 1:5, 1:6, 1:7, 1:8, 1:9, or 1:10. In further examples, the sub-cycle ratio (N₁:N₂) (for a desired Ga/Nb ratio in the niobium gallium oxide layer) may be 10:1, 9:1, 8:1, 7:1, 6:1, 5:1, 4:1, 3:1, 2:1, or 1:1. In yet further examples, the sub-cycle ratio (N₁:N₂) (for a desired Ga/Nb ratio in the niobium gallium oxide layer) may be greater than 1:2, 1:3, 1:5, 1:7, or 1:10. In additional examples, the sub-cycle ratio (N₁:N₂) (for a desired Ga/Nb ratio in the niobium gallium oxide layer) may be less than 10:1, 7:1, 5:1, 3:1, or 2:1.

In accordance with additional particular examples of the disclosure, the first sub-cycle (204) may comprise providing the first metal precursor comprising gallium to the reaction chamber (sub-step 206) and providing a first reactant comprising a nitrogen reactant to the reaction chamber (sub-step 208), and the second sub-cycle may comprise providing a second metal precursor comprising a niobium precursor to the reaction chamber (sub-step 214) and providing a second reactant comprising an addition nitrogen reactant to the reaction chamber (sub-step 216). In such examples, the nitrogen reactant (i.e., the first reactant) and the additional nitrogen reactant (i.e., the second reactant) may comprise the same nitrogen reactant or alternatively may comprise different nitrogen reactants. In such examples, the dipole layer deposited by the super-cycle cyclical deposition process 202 may comprise a niobium gallium nitride layer (NbGaN). In such examples, the sub-cycle ratio (N₁:N₂) may be varied to achieve a desired Ga/Nb ratio composition in the deposited niobium gallium nitride layer, as described above. For example, the sub-cycle ratio (N₁:N₂) (for a desired Ga/Nb ratio in the niobium gallium nitride layer) may be 1:1, 1:2, 1:3, 1:4, 1:5, 1:6, 1:7, 1:8, 1:9, or 1:10. In further examples, the sub-cycle ratio (N₁:N₂) (niobium gallium nitride layer) may be 10:1, 9:1, 8:1, 7:1, 6:1, 5:1, 4:1, 3:1, 2:1, or 1:1. In yet further examples, the sub-cycle ratio (N₁:N₂) (for a desired Ga/Nb ratio in the niobium gallium nitride layer) may be greater than 1:2, 1:3, 1:5, 1:7, or 1:10. In additional examples, the sub-cycle ratio (N₁:N₂) (for a desired Ga/Nb ratio in the niobium gallium nitride layer) may be less than 10:1, 7:1, 5:1, 3:1, or 2:1.

In accordance with examples of the disclosure, a dipole layer comprising a ternary gallium material deposited by the super-cycle cyclical deposition process 202 may comprise a mixture of one or more individual oxides. In such examples and wherein the second metal precursor comprises niobium, the dipole layer may comprise a gallium oxide (GaO) and a niobium oxide (NbO) (e.g., constituting a NbGaO dipole layer). In such examples and wherein the second metal precursor comprises titanium, the dipole layer can comprise a gallium oxide (GaO) and a titanium oxide (TiO) (e.g., constituting a TiGaO dipole layer). In such examples and wherein the second metal precursor comprises vanadium, the dipole layer can comprise a gallium oxide (GaO) and a vanadium oxide (VO) (e.g., constituting a VGaO dipole layer). In such examples and wherein the second metal precursor comprises tungsten, the dipole layer can comprise a gallium oxide (GaO) and a tungsten oxide (WO) (e.g., constituting a WGaO dipole layer).

In accordance with examples of the disclosure, a dipole layer deposited by the super-cycle cyclical deposition process 202 may comprise a mixture of one or more individual nitrides. In such examples and wherein the second metal precursor comprises niobium, the dipole layer can comprise a gallium nitride (GaN) and a niobium nitride (NbN) (e.g., constituting a NbGaN dipole layer). In such examples and wherein the second metal precursor comprises titanium, the dipole layer can comprise a gallium nitride (GaN) and a titanium nitride (TiN) (e.g., constituting a TiGaN dipole layer). In such examples and wherein the second metal precursor comprises vanadium, the dipole layer can comprise a gallium nitride (GaN) and a vanadium nitride (VN) (e.g., constituting a VGaN dipole layer). In such examples and wherein the second metal precursor comprises tungsten, the dipole layer can comprise a gallium nitride (GaN) and a tungsten oxide (WN) (e.g., constituting a WGaN dipole layer).

In accordance with examples of the disclosure, a dipole layer deposited by the super-cycle cyclical deposition process 202 may comprise a mixture of one or more individual carbides. In such examples and wherein the second metal precursor comprises niobium, the dipole layer can comprise a gallium carbide (GaC) and a niobium carbide (NbC) (e.g., constituting a NbGaC dipole layer). In such examples and wherein the second metal precursor comprises titanium, the dipole layer can comprise a gallium carbide (GaC) and a titanium carbide (TiC) (e.g., constituting a TiGaC dipole layer). In such examples and wherein the second metal precursor comprises vanadium, the dipole layer can comprise a gallium carbide (GaC) and a vanadium carbide (VC) (e.g., constituting a VGaC dipole layer). In such examples and wherein the second metal precursor comprises tungsten, the dipole layer can comprise a gallium carbide (GaC) and a tungsten oxide (WC) (e.g., constituting a WGaC dipole layer).

In accordance with additional examples of the disclosure, a super-cycle cyclical deposition process may include a first sub-cycle which comprises contacting the substrate with a first metal precursor comprising a gallium, contacting the substrate with a second metal precursor, and contacting the substrate with a first reactant comprising one or more of an oxygen reactant, a nitrogen reactant, or a carbon reactant. In such examples, the second sub-cycle 212 may remain as illustrated in FIG. 2 and as described above. In such examples the super-cycle cyclical deposition process comprising the two sub-cycles and may be written as: {[gallium precursor+second metal precursor+first reactant]×N₄+[second metal precursor+second reactant]×N₅}×N₆, where N₄, N₅, and N₆ are real integers, and the square brackets represent one sub-cycle whereas the curved brackets represent on super-cycle. In such examples, the first sub-cycle may deposit at least one of a NbGaO, VGaO, TiGaO, WGaO when employing an oxygen reactant as the first reactant. In further examples, the first sub-cycle may deposit at least one of a NbGaN, VGaN, TiGaN, WGaN when employing a nitrogen reactant as the first reactant. In further examples, the first sub-cycle may deposit at least one of a NbGaC, VGaC, TiGaC, WGaC when employing a carbon reactant as the first reactant. In addition, the second sub-cycle may deposit at least one of NbO, NbN, NbC, VO, VN, VC, TiO, TiN, TiC, WO, WN, or WC. In accordance with examples of the disclosure, the ratio of the number of times performing the first sub-cycle (N₄) in comparison with the number times performing the second sub-cycle (N₅) is as previously described previous with reference to (N₁:N₂).

In accordance with further examples of the disclosure, a super-cycle cyclical deposition process may include a first sub-cycle which may remain as illustrated in FIG. 2 and as described above. In such examples, the second sub-cycle may comprise contacting the substrate with a second metal precursor, contacting the substrate with a first metal precursor comprising a gallium, and contacting the substrate with a first reactant comprising one or more of an oxygen reactant, a nitrogen reactant, or a carbon reactant. In such examples the super-cycle cyclical deposition process comprising the two sub-cycles and may be written as: {[gallium precursor+first reactant]×N₇+[second metal precursor+gallium precursor+second reactant]×N₈}×N₉, where N₇, N₈, and No are real integers, and the square brackets represent one sub-cycle whereas the curved brackets represent on super-cycle. In such examples, the first sub-cycle may deposit at least one of a GaO, GaN, or GaC. Further, in such examples, the second sub-cycle may deposit at least one of NbGaO, VGaO, TiGaO, or WGaO when employing an oxygen reactant as the second reactant. In further examples, the second sub-cycle may deposit at least one of a NbGaN, VGaN, TiGaN, or WGaN when employing a nitrogen reactant as the second reactant. In further examples, the second sub-cycle may deposit at least one of a NbGaC, VGaC, TiGaC, or WGaC when employing a carbon reactant as the second reactant. In accordance with examples of the disclosure, the ratio of the number of times performing the first sub-cycle (N₇) in comparison with the number times performing the second sub-cycle (N₈) is as previously described previous with reference to (N₁:N₂).

### Specific To ALD Deposition and Niobium Gallium Oxide/Nitride

In accordance with examples of the disclosure, the cyclical deposition processes as described above may comprise an atomic layer deposition (ALD) process. Various embodiments therefore include methods for depositing a dipole layer on a substrate including a surface high-k dielectric layer (such as high-k dielectric layer 312 of FIG. 3).

In accordance with examples of the disclosure, the atomic layer deposition (ALD) process may comprise performing a plurality of super-cycles. In such examples, each super-cycle may comprise a gallium sub-cycle and a niobium sub-cycle. In some embodiments, the gallium sub-cycle may comprise alternately and sequentially contacting the substrate with a gallium precursor (as described above) and a first reactant comprising at least one of a first oxygen reactant, a first nitrogen reactant, or a first carbon reactant (as described above). In some embodiments, the niobium sub-cycle may comprises alternately and sequentially contacting the substrate with a niobium precursor (as described above) and a second reactant comprising at least one of a second oxygen reactant, a second nitrogen reactant, or a second carbon reactant (as described above).

In various embodiments of the atomic layer deposition process, the first reactant and the second reactant may comprise an oxygen reactant and the dipole layer may comprise a niobium gallium oxide layer. In such examples a super-cycle of the atomic layer deposition process may be written as: {[gallium precursor+first oxygen reactant]×N₁₀+[niobium precursor+second oxygen reactant]×N₁₁}×N₁₂, where N₁₀, N₁₁, and N₁₂ are real integers, and the square brackets represent one sub-cycle whereas the curved brackets represent one super-cycle. In such examples, the ratio of the number of times performing the first sub-cycle (N₁₀) in comparison with the number times performing the second sub-cycle (N₁₁) is as previously described previous with reference to (N₁:N₂). For example, the sub-cycle ratio (N₁₀:N₁₁) (for a desired Ga/Nb ratio in the niobium gallium oxide layer) may be 1:1, 1:2, 1:3, 1:4, 1:5, 1:6, 1:7, 1:8, 1:9, or 1:10. In further examples, the sub-cycle ratio (N₁₀:N₁₁) (niobium gallium oxide layer) may be 10:1, 9:1, 8:1, 7:1, 6:1, 5:1, 4:1, 3:1, 2:1, or 1:1. In yet further examples, the sub-cycle ratio (N₁₀:N₁₁) (for a desired Ga/Nb ratio in the niobium gallium oxide layer) may be greater than 1:2, 1:3, 1:5, 1:7, or 1:10. In additional examples, the sub-cycle ratio (N₁₀:N₁₁) (for a desired Ga/Nb ratio in the niobium gallium oxide layer) may be less than 10:1, 7:1, 5:1, 3:1, or 2:1.

In various embodiments of the atomic layer deposition process, the first reactant and the second reactant may comprise a nitrogen reactant and the dipole layer may comprise a niobium gallium nitride layer. In such examples a super-cycle of the atomic layer deposition process may be written as: {[gallium precursor+first nitrogen reactant]×N₁₃+[niobium precursor+second nitrogen reactant]×N₁₄}×N₁₅, where N₁₃, N₁₄, and N₁₅ are real integers, and the square brackets represent one sub-cycle whereas the curved brackets represent one super-cycle. In such examples, the ratio of the number of times performing the first sub-cycle (N₁₃) in comparison with the number times performing the second sub-cycle (N₁₄) is as previously described previous with reference to (N₁:N₂). For example, the sub-cycle ratio (N₁₃:N₁₄) (for a desired Ga/Nb ratio in the niobium gallium nitride layer) may be 1:1, 1:2, 1:3, 1:4, 1:5, 1:6, 1:7, 1:8, 1:9, or 1:10. In further examples, the sub-cycle ratio (N₁₃:N₁₄) (niobium gallium nitride layer) may be 10:1, 9:1, 8:1, 7:1, 6:1, 5:1, 4:1, 3:1, 2:1, or 1:1. In yet further examples, the sub-cycle ratio (N₁₃:N₁₄) (for a desired Ga/Nb ratio in the niobium gallium nitride layer) may be greater than 1:2, 1:3, 1:5, 1:7, or 1:10. In additional examples, the sub-cycle ratio (N₁₃:N₁₄) (for a desired Ga/Nb ratio in the niobium gallium nitride layer) may be less than 10:1, 7:1, 5:1, 3:1, or 2:1.

### Nitridation of the Dipole Layer

In accordance with examples of the disclosure, the method 100 (FIG. 1) can optionally include one more post-deposition treatments of the deposited dipole layer. For example, such optional post deposition treatments of the dipole layer can be employed to alter one or more of the properties of the ternary gallium material dipole layer. Such alteration to the properties of the dipole layer may be employed to improve the dipole properties of the layer and/or improve the sensitivity of the layer to subsequent processes employed in the fabrication of a semiconductor device.

Therefore, in accordance with examples of the disclosure, method 100 (FIG. 1) can optionally comprise contacting the dipole layer with a nitrogen-containing reactant (step 112). In such examples contacting the dipole layer with the nitrogen-containing reactant may nitridize a portion of the dipole layer (step 112). In some embodiments the substrate, with the dipole layer thereon, may be heated to a temperature between 500° C. and 1000° C., or between 600° C. and 950° C., between 700° C. and 900° C. In some embodiments the nitrogen-containing reactant used for nitriding a portion of the dipole layer may comprise one or more of ammonia (NH₃), or a gas mixture of ammonia (NH₃) and hydrogen (H₂).

### Properties of the Dipole Layer

FIG. 4 illustrates the substrate 300 (of FIG. 3) after the deposition of the dipole layer, and the optional nitridation of the dipole layer. As illustrated in FIG. 4, the dipole layer 402 is disposed over the dielectric material 314 and particularly over the high-k dielectric layers. In some embodiments, the dipole layer 402 is deposited directly on the high-k dielectric layer 312.

In accordance with examples of the disclosure, the dipole layer 402 may be deposited with an average layer thickness between 30 Angstroms and 5 Angstroms, between 25 Angstroms and 10 Angstroms, or between 20 Angstroms and 15 Angstroms. In some embodiments the dipole layer 402 may be deposited with an average layer thickness of less than 30 Angstroms, less than 25 Angstroms, or less than 20 Angstroms. In some embodiments the dipole layer may be deposited with an average layer thickness of greater than 15 Angstroms, greater than 25 Angstroms, or greater than 30 Angstroms

### Integration Description

The various embodiments of the disclosure also include methods for forming a semiconductor device structure employing the dipole layers of the present disclosure. In some embodiments the dipole layers deposited by methods previously described may be employed as threshold voltage shifting layers for modifying the flat-band voltage of a semiconductor device structure. In such embodiments, a substrate (e.g., substrate 300 of FIG. 3) with a ternary gallium material dipole layer deposited thereon can be subjected to a thermal treatment, such as a thermal annealing process, to diffusion species from the dipole layer into the underling layers to induce a threshold voltage shift in a resulting semiconductor device structure fabricated from the substrate.

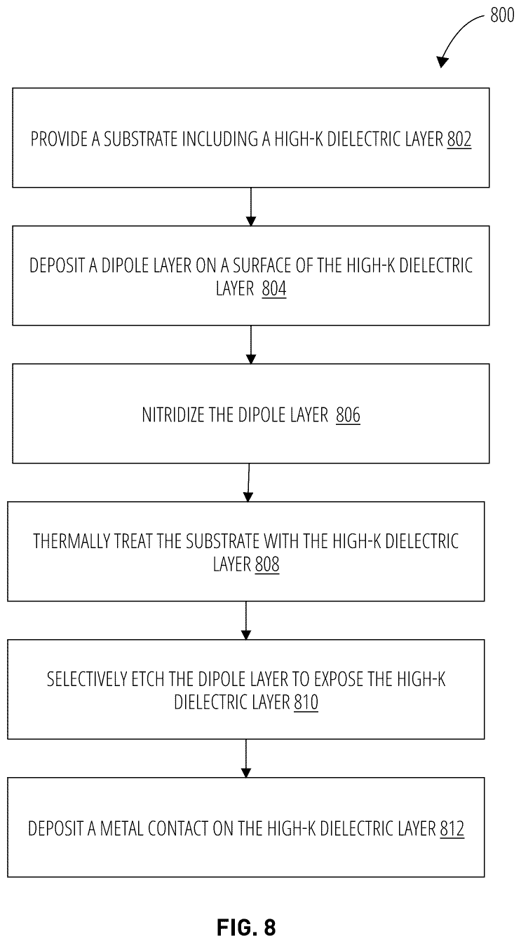

In accordance with various embodiments, FIG. 8 illustrates a method 800 for forming a semiconductor device structure. Method 800 may comprise providing a substrate including a high-k dielectric layer (step 802). In such examples the substrate may comprise substrate 300 of FIG. 3 as previously described.

In accordance with examples of the disclosure, method 800 may further comprise depositing a dipole layer on a surface of the high-k dielectric layer by performing a plurality of super-cycles of an atomic layer deposition process (step 804). In such examples, each super-cycle may comprise a gallium sub-cycle and a niobium sub-cycle. In some embodiments, the gallium sub-cycle may comprise alternately and sequentially contacting the substrate with a gallium precursor and a first reactant comprising at least one of a first oxygen reactant, a first nitrogen reactant, or a first carbon reactant. In some embodiments, the second metal sub-cycle may comprise alternately and sequentially contacting the substrate with a second metal precursor comprising one or more of a niobium precursor, a titanium precursor, a vanadium precursor, or a tungsten precursor and a second reactant comprising at least one of a second oxygen reactant, a second nitrogen reactant, or a second carbon reactant. Details regarding step 804 are described in greater herein above.

In accordance with examples of the disclosure, method 800 may also comprise nitriding the dipole layer by contacting the dipole layer with a nitrogen reactant (step 806). In such examples, contacting the dipole layer with the nitrogen-containing reactant may comprise contacting the dipole layer with at least one of ammonia (NH₃), or a gas mixture of ammonia (NH₃) and hydrogen (H₂). In such examples, the nitriding of the dipole layer may be performed at temperature between 500° C. and 1000° C.

In accordance with examples of the disclosure, method 800 may further comprise thermally treating the substrate with the high-k dielectric layer and the dipole layer thereon. In such examples, the thermal treatment may comprise a thermal annealing process where the substrate is heated to a temperature between 500° C. and 1000° C. In various embodiments, one or more additional layers of material may be formed over the dipole layer prior to thermally annealing the substrate. FIG. 5 illustrates a semiconductor structure 500 which comprises the semiconductor structure 400 of FIG. 4 after forming an additional layer 502 over the dipole layer 402. In such examples, the additional layer 502 (or layers) may be employed to protect the underlying layers (e.g., the dipole layer 402, the high-k dielectric layer 312, the interface layer 310, and the semiconductor 302) during the thermal annealing process. In some embodiments, the additional layer 502 may comprise one or more of a metal, a metal oxide, a metal nitride, a metal carbide, or a semiconductor. In one aspect, the additional layer 502 may comprises one or more of amorphous silicon or a metal nitride, such as, titanium nitride (TiN), for example. The step of thermally treating the substrate (and particularly the ternary gallium material dipole layer) may be employed to diffuse species from the dipole layer into the underlying layers beneath the dipole layer.

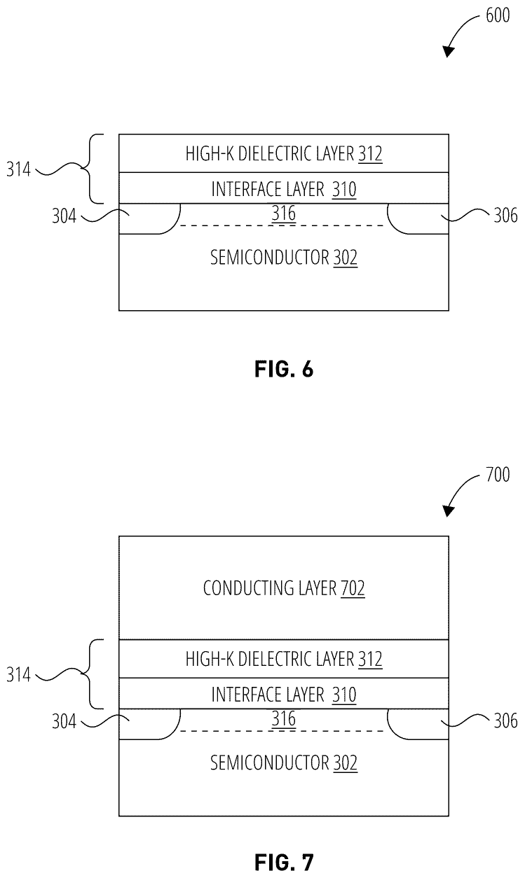

In accordance with further examples of the disclosure, method 800 may also comprise selectively etching the dipole layer to expose the high-k dielectric layer (step 810). In some embodiments, a first selective etch process may be employed to remove the additional layer 502 (if present) and a second selective etch process may be employed to remove the dipole layer 402. In some embodiments, a single selective etch process is employed to remove both the additional layer 502 and the dipole layer 402. As used herein, the term “selective etch” may refer to an etch process that removes the dipole layer 402 and/or the additional layer 502 (if present) without etching, or without significantly etching, the high-k dielectric layer 312. For example, FIG. 6 illustrates a semiconductor structure 600 which comprises semiconductor structure 500 of FIG. 5 after completion of the selective etch of the dipole layer 402 and the additional layer 502 (if present). As illustrated in FIG. 6 the selective etch exposes the high-k dielectric layer 312.

In accordance with further examples of the disclosure, method 800 may further comprise forming a conducting layer on the high-k dielectric layer. For example, FIG. 7 illustrates a semiconductor device structure 700 which comprises the semiconductor structure 600 of FIG. 6 after forming a conducting layer 702 on the high-k dielectric layer 312. In such examples, the conducting layer 702 may comprise a metal, such as a refractory metal, or the like. By way of examples, the conducting layer 702 can be or include one or more of titanium nitride, vanadium nitride, a metal stack including titanium nitride and a metal (e.g., W, Co, Ru, Mo) or titanium nitride, titanium aluminum carbon, and titanium nitride, tungsten, tungsten carbon nitride, cobalt, copper, molybdenum, ruthenium, or the like.

Vth Shift From the Dipole Layer

In accordance with examples of the disclosure, the dipole layer comprising a ternary gallium material having one or more of the compositions as described previously (e.g., NbGaO, NbGaN, etc.) can induce a threshold shift in a semiconductor device structure, such as, semiconductor device structure 700 of FIG. 7. In one aspect, the dipole layer may induce a threshold voltage shift of between 5 mV and 100 mV per Angstrom of thickness of the dipole layer. In another aspect, the dipole layer may induce a threshold voltage shift of between 10 mV and 50 mV per Angstrom of thickness of the dipole layer. In a further aspect, the dipole layer may induce a threshold voltage shift of between 20 mV and 30 mV per Angstrom of thickness of the dipole layer. As previously described the average dipole layer thickness and/or the composition of the dipole layer can be manipulated to obtain a desired shift in work function and/or threshold voltage. Further in such examples, the dipole layer comprising a ternary gallium material of the present disclosure may induce a desired threshold voltage shift without impacting, or significantly impacting, the equivalent oxide thickness (EOT) of a semiconductor device structure (such as semiconductor device structure 700 of FIG. 7).

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method for forming a semiconductor structure, the method comprising:
providing a substrate within a reaction chamber, the substrate comprising a high-k dielectric layer;
depositing a dipole layer comprising a ternary gallium material on a surface of the high-k dielectric layer by performing one or more cycles of a cyclical deposition process; wherein each cycle of the cyclical deposition process comprises:
providing a first metal precursor comprising gallium to the reaction chamber;
providing a second metal precursor comprising a second metal to the reaction chamber; and
providing a first reactant to the reaction chamber, the first reactant comprising at one of an oxygen reactant, a nitrogen reactant, or a carbon reactant.

2. The method of claim 1, wherein the second metal precursor comprises one or more of a niobium precursor, a titanium precursor, a vanadium precursor, or a tungsten precursor.

3. The method of claim 2, wherein each cycle of the cyclical deposition process further comprises a super-cycle, each super-cycle comprising a first sub-cycle for depositing a first material comprising gallium and a second sub-cycle for depositing a second material comprising the second metal.

4. The method of claim 3, wherein the first sub-cycle and the second sub-cycle are performed with a sub-cycle ratio equal to greater than 1:2 in the super-cycle.

5. The method of claim 3, wherein the first sub-cycle comprises, providing the first metal precursor comprising gallium to the reaction chamber and providing the oxygen reactant to the reaction chamber, and the second sub-cycle comprising providing a niobium precursor to the reaction chamber and providing a second oxygen reactant to the reaction chamber.

6. The method of claim 3, wherein the first sub-cycle comprises, providing the first metal precursor comprising gallium to the reaction chamber and providing the nitrogen reactant to the reaction chamber, and the second sub-cycle comprising providing a niobium precursor to the reaction chamber and providing a second nitrogen reactant to the reaction chamber.

7. The method of claim 2, further comprising contacting the dipole layer with a nitrogen-containing reactant thereby nitriding a portion of the dipole layer.

8. The method of claim 7, wherein contacting the dipole layer with the nitrogen-containing reactant is performed at temperature between X° C. and X° C.

9. A method for depositing a dipole layer on a substrate including a surface high-k dielectric layer by an atomic layer deposition (ALD) process, the ALD process comprising:
performing a plurality of super-cycles, each super-cycle comprising a gallium sub-cycle and a niobium sub-cycle;
wherein the gallium sub-cycle comprises alternately and sequentially contacting the substrate with a gallium precursor and a first reactant comprising at least one of a first oxygen reactant, a first nitrogen reactant, or a first carbon reactant; and
wherein the niobium sub-cycle comprises alternately and sequentially contacting the substrate with a niobium precursor and a second reactant comprising at least one of a second oxygen reactant, a second nitrogen reactant, or a second carbon reactant.

10. The method of claim 9, wherein the gallium sub-cycle and the niobium sub-cycle are performed with a sub-cycle ratio equal to or greater than 1:2 in the super-cycle.

11. The method of claim 9, wherein the first reactant and the second reactant comprise an oxygen reactant and the dipole layer comprise a niobium gallium oxide layer.

12. The method of claim 9, wherein the first reactant and the second reactant comprise a nitrogen reactant and the dipole layer comprises a niobium gallium nitride layer.

13. The method of claim 9, further comprising contacting the dipole layer with a nitrogen-containing reactant thereby nitriding a portion of the dipole layer.

14. The method of claim 13, wherein contacting the dipole layer with the nitrogen-containing reactant is performed at temperature between X° C. and X° C.

15. The method of claim 14, wherein the nitrogen-containing reactant comprises ammonia (NH₃).

16. A method of forming a semiconductor device, the method comprising:
providing a substrate comprising a high-k dielectric layer;
depositing a dipole layer on a surface of the high-k dielectric layer by performing a one or more of super-cycles of an atomic layer deposition process, each super-cycle comprising a gallium sub-cycle and a second metal sub-cycle;
contacting the dipole layer with a nitrogen-containing reactant thereby nitriding a portion of the dipole layer;
thermally treating the substrate with the high-k dielectric layer and the dipole layer thereon at temperature between X° C. and X° C.;
selectively etching the dipole layer to expose the high-k dielectric layer; and
depositing a conducting layer on the high-k dielectric layer.

17. The method of claim 16, wherein the gallium sub-cycle comprises alternately and sequentially contacting the substrate with a gallium precursor and a first reactant comprising at least one of a first oxygen reactant, a first nitrogen reactant, or a first carbon reactant.

18. The method of claim 17, wherein the second metal sub-cycle comprises alternately and sequentially contacting the substrate with a second metal precursor comprising one or more of a niobium precursor, a titanium precursor, a vanadium precursor, or a tungsten precursor and a second reactant comprising at least one of a second oxygen reactant, a second nitrogen reactant, or a second carbon reactant.

19. The method of claim 16, wherein contacting the dipole layer with the nitrogen-containing reactant comprises contacting the dipole layer with ammonia (NH₃) at temperature between X° C. and X° C.

20. The method of claim 19, wherein the dipole layer provides a voltage shift to the semiconductor device between 10 mV and 50 mV per Angstrom of thickness of the deposited dipole layer.
